(19) United States
(12) Patent Application Publication
(10) Pub. No.: US 2019/0296737 A1
(43) Pub. Date: Sep. 26, 2019

(54) DIODE CIRCUIT FOR EFFICIENT OPERATION

(71) Applicant: SEMICONDUCTOR COMPONENTS INDUSTRIES, LLC, Phoenix, AZ (US)

(72) Inventor: Adam John WHITWORTH, Mountain View, CA (US)

(73) Assignee: SEMICONDUCTOR COMPONENTS INDUSTRIES, LLC, Phoenix, AZ (US)

(21) Appl. No.: 16/263,659

(22) Filed: Jan. 31, 2019

Related U.S. Application Data
(60) Provisional application No. 62/647,322, filed on Mar. 23, 2018.

(51) Int. Cl. H03K 17/567; H01L 29/872; H01L 31/0443

(52) U.S. Cl. CPC H03K 17/567; H01L 31/0443; H01L 29/872

(57) ABSTRACT

A circuit and method for reducing the reverse leakage current in a reverse-biased diode device, such as a Schottky diode, is disclosed. The diode device is electrically coupled between an N-channel depletion mode device and a P-channel depletion mode device, and the gates of the depletion mode devices are electrically coupled to opposite terminals of the circuit so that both are either in an ON state or an OFF state, based on a voltage applied to terminals of the circuit. When the circuit is forward-biased both depletion mode devices are in an ON state and when the diode device is reversed biased both the depletion mode devices are in the OFF state. The depletion mode devices in the OFF state reduce a reverse leakage current of the diode device. This reduction is useful for applications that require efficient diode operation, such as solar cell systems.

### CROSS-REFERENCE TO RELATED APPLICATIONS

This application claims the benefit of U.S. provisional patent application No. 62/647,322, filed on Mar. 23, 2018, the entire contents of which are incorporated herein by reference.

### TECHNICAL FIELD

This description relates to a diode circuit with a forward voltage and a leakage current suitable for applications that may require efficient diode operation, such as photovoltaic arrays.

### BACKGROUND

The efficiency of a diode device (i.e., diode) may be characterized by a voltage drop (i.e., forward voltage) across the diode when biased for conduction (i.e., forward-biased) and a current (i.e., leakage current) through the diode when biased for non-conduction (i.e., reverse-biased). The forward voltage and the leakage current of some diode may be too high for some applications that may require efficient diode operation. Thus, a need exists for systems, methods, and apparatus to address the shortfalls of present technology and to provide other new and innovative features.

### SUMMARY

In one general aspect, the disclosure describes a diode circuit that includes a diode device (e.g., Schottky diode), an N-channel (i.e., N-type) depletion mode device (e.g., MOSFET, JFET), and a P-channel (i.e., P-type) depletion mode device (e.g., MOSFET, JFET). The diode device has an anode and a cathode. The N-channel depletion mode device is electrically coupled between the cathode of the diode device and an output terminal of the diode circuit, and the P-channel depletion mode device is electrically coupled between the anode of the diode device and an input terminal of the diode circuit.

In another general aspect, the disclosure describes a method for reducing a reverse leakage current in a diode circuit. In the method, a reverse-bias voltage is applied to terminals of the diode circuit. The reverse-bias voltage generates the reverse leakage current through a diode, which is electrically coupled between a pair of depletion mode devices in the diode circuit. The reverse-bias voltage applied to the diode circuit is then increased to a voltage that is at (or above) a threshold voltage to configure the pair of depletion mode devices in an OFF state. Next, the reverse leakage current is blocked using the depletion mode devices in the OFF state to reduce the reverse leakage current in the diode circuit.

In another general aspect, the disclosure describes a solar cell system. The solar cell system includes a plurality of solar cells that are electrically coupled in series. The solar cell system also includes diode circuits that are each electrically coupled in parallel with each of the plurality of solar cells. When a solar cell is illuminated, the electrically coupled diode circuit is reverse-biased and blocks current. When a solar cell is shaded, the electrically coupled diode circuit is forward-biased and conducts current to bypass the shaded solar cell. The diode circuit includes a Schottky diode, an N-channel depletion mode device, and a P-channel depletion mode device. The diode device has an anode and a cathode. The N-channel depletion mode device is electrically coupled between the cathode of the diode device and an output terminal of the diode circuit, and The P-channel depletion mode device is electrically coupled between the anode of the diode device and an input terminal of the diode circuit.

In a possible implementation, the N-channel depletion mode device, the P-channel depletion mode device, and the Schottky diode are in an ON state when the diode circuit is forward-biased; and the N-channel depletion mode device, the P-channel depletion mode device, and the Schottky diode are in an OFF state when the diode circuit is reverse-biased.

### BRIEF DESCRIPTION OF THE DRAWINGS

FIGS. 1A and 1B are diagrams that illustrate a diode circuit and operation thereof.

FIG. 2 is a diagram that illustrates an implementation of the diode circuit shown in FIGS. 1A and 1B.

FIG. 3A illustrates a diode circuit without depletion devices.

FIG. 3B illustrates a possible implementation of a diode circuit with depletion devices.

FIG. 4 is a graph showing a possible operation of the diode circuits of FIGS. 3A and 3B.

FIG. 5A is a graph showing a scaled first portion of the graph of FIG. 4 for clarity.

FIG. 5B is a graph showing a scaled second portion of the graph of FIG. 4 for clarity.

FIG. 6 is a flowchart of a method for reducing leakage current according to an implementation of the present disclosure.

FIGS. 7A and 7B are diagrams that illustrate diode circuits included in a possible implementation of a solar cell system.

In the drawings, like elements are referenced with like reference numerals.

### DETAILED DESCRIPTION

The operation of a diode is based on the voltage (i.e., bias) applied to the terminals (i.e., anode and cathode) of the diode. The diode is in a forward-bias (i.e., ON) condition when the voltage applied to the anode is higher than the cathode. The diode is in a reverse-bias (i.e., OFF) condition when the voltage applied to the cathode is higher than the anode. In the forward-bias condition, the diode conducts a current (i.e., has a low resistance). Accordingly, the operation of a diode in the ON condition may be characterized by its forward voltage drop (i.e., forward voltage). In the reverse-bias condition, the diode resists the flow of current. Accordingly, the operation of a diode in the OFF condition may be characterized by its reverse leakage current (i.e., leakage current, reverse current).

In some applications, such as those that may require efficient operation of the diode, it is desirable that the leakage current in the OFF condition and the forward voltage in the ON condition be as small as possible. The disclosed circuit and techniques can provide diode operation with a low forward voltage and a low reverse leakage current. The disclosed circuits and techniques may be implemented with any type of diode (e.g., PN semiconductor, PIN semiconductor, light emitting, etc.) to limit reverse leakage current but can provide further advantages when implemented with Schottky diodes.

A Schottky diode is a metal-semiconductor junction diode that has a low forward voltage drop (e.g., less than 0.5 volts). The low forward voltage of the Schottky diode corresponds to less energy dissipated than a conventional (e.g., semiconductor junction) diode. The low energy dissipation under forward-bias makes the Schottky diode suitable for applications that require efficient operation, such as in the field of power generation (e.g., photovoltaic arrays, power supplies, etc.).

When reversed biased, the Schottky diode can have a higher leakage current (e.g., approximately 10 milliamps (mA)) than a corresponding semiconductor junction diode. The high leakage current problem is made worse as the size of the Schottky diode is increased (e.g., to carry higher currents). This trend is problematic because increasing the size of a Schottky diode typically lowers the forward voltage drop. In other words, while it may be desirable to increase the size of a Schottky diode to reduce its forward voltage drop, doing so can increase a relatively high leakage current even further. Thus, any gains in efficiency resulting from a lowered forward voltage drop can be lost by (e.g., outweighed by) a corresponding increased leakage in the reverse-bias condition. Implementations of the circuits and methods described herein provide a technical solution to this technical problem by facilitating diode operation that provides both a low (e.g., less than 0.5 volts) forward voltage drop in a forward-bias condition and a low leakage current (e.g., approximately 10 micro amps (μA)) in a reverse-bias condition.

Achieving low forward voltage and low reverse leakage current in a Schottky diode operating alone may not be possible. Accordingly, for the implementations described herein, additional circuitry is used in conjunction with a Schottky diode to achieve a low voltage drop when forward-biased and a low leakage current when reverse-biased. The additional circuitry can be used in conjunction with a Schottky diode because the Schottky diode alone may not inherently have simultaneously low forward voltage and low reverse leakage current. The additional circuitry associated with the Schottky diode can be referred to as Schottky support circuitry (i.e., support circuitry). The Schottky diode and Schottky support circuit can collectively be referred to as a Schottky diode circuit (i.e., diode circuit).

The diode circuits described herein can have (e.g., simultaneously have) an ultra-low leakage current when reverse-biased and can also have a low voltage drop when forward-biased. Specifically, the diode circuits described herein can include depletion mode devices (as support circuitry) that are coupled to a Schottky diode and enable desirable low voltage forward-biasing operation and ultra-low leakage reverse-biasing operation. The diode circuits described herein can be contrasted with circuits, associated with Schottky diodes, that have various analog integrated circuits, active circuits, and/or so forth, which consume power in an undesirable fashion and/or may not have a desirable forward voltage drop and reverse-bias current.

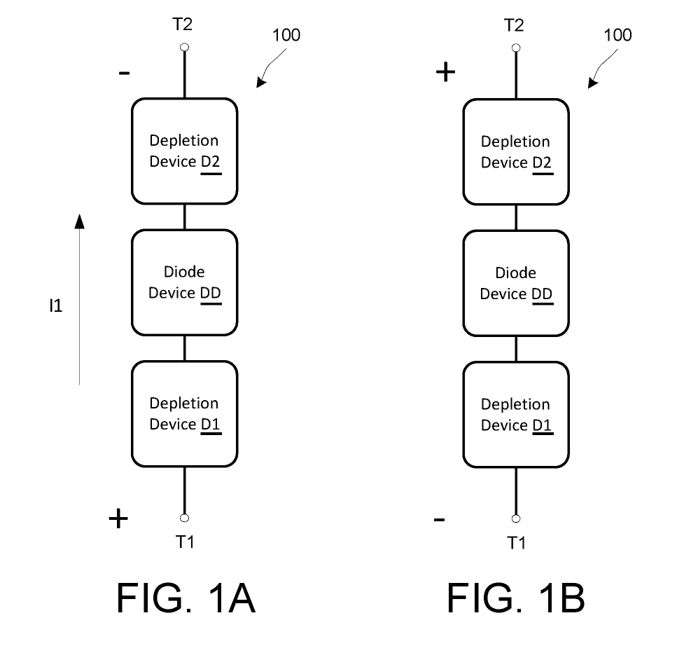

FIGS. 1A and 1B are diagrams that illustrate a diode circuit 100 and operation thereof. As shown in FIGS. 1A and 1B, the diode circuit 100 includes a diode device DD and depletion devices D1 and D2. The diode device DD is electrically coupled between the depletion devices D1 and D2, which can be considered, or can be included as, support circuitry. The diode device DD is serially connected between the depletion devices D1, D2. The diode device DD can be, in some implementations, a Schottky diode, and/or another type of diode. FIG. 1A illustrates forward-biased operation of the diode circuit 100 (and diode device DD) and FIG. 1B illustrates reverse-biased operation of the diode circuit 100 (and diode device DD).

When the diode circuit 100 is forward-biased as illustrated in FIG. 1A, forward current I1 flows from terminal T1 (i.e., input terminal) to terminal T2 (i.e., output terminal). The diode circuit 100 is forward-biased when a voltage (e.g., electrical potential) at terminal T1 is higher than a voltage at terminal T2. In this implementation, both of the depletion devices D1 and D2, which are depletion-mode devices, are normally in an ON-state (e.g., normally-ON devices) and are conducting when the diode circuit 100 is forward-biased. In other words, the depletion devices D1 and D2 do not block (i.e., conduct) forward current I1 from flowing in a forward-biased direction (as shown in FIG. 1A) through the diode device DD.

The depletion devices D1 and D2 can each have a relatively low resistance. The depletion devices D1 and D2 can have a low ON-resistance (e.g., resistance when in the ON-state) relative to a resistance of the diode device DD when the diode device DD is forward-biased. The depletion devices D1 and D2 can have a low ON-resistance relative to the resistance of the diode device DD when forward-biased so that the overall resistance between terminals T1 and T2, when the diode circuit 100 is forward-biased, is approximately the same as, or only a fraction larger than, the forward-biased resistance of the diode device DD alone.

When the diode circuit 100 is reverse-biased as illustrated in FIG. 1B, current is substantially blocked from flowing from terminal T2 to terminal T1. The diode circuit 100 is reverse-biased when a voltage (e.g., electrical potential) at terminal T2 is higher than a voltage at terminal T1. When the diode circuit 100 is reverse-biased, both of the depletion devices D1 and D2 are in an OFF-state (i.e., OFF) and are blocking (e.g., not conducting). In other words, the depletion devices D1 and D2 block current from flowing in a reverse-biased direction through the diode device DD.

Because of inclusion of the depletion devices D1 and D2, the diode device DD can be made larger than without depletion devices D1 and D2. Specifically, the diode device DD diode may be increased in size to achieve a low forward voltage when forward-biased. However, the increased size of the Schottky diode that would otherwise result in a large leakage current when reverse-biased can be mitigated by the depletion devices D1 and D2 (which will have a high impedance when reverse-biased).

As a specific example, the diode device DD can have a leakage current on the order of milliamps (e.g., 1 mA, 10 mA, 50 mA). In contrast, the leakage of the depletion devices D1, D2 in an OFF state can be significantly lower (e.g., 1000× lower, on the order of micro-amps (e.g., 10 μA)). The relatively low leakage current of the depletion devices D1, D2 in the OFF state (i.e., off-leakage), which are serially connected with the diode device DD, can restrict the overall leakage of the diode circuit 100.

A depletion device may be implemented in various ways. For example, a depletion device may be implemented as a depletion mode metal oxide semiconductor field effect transistor (i.e., MOSFET) or a depletion device may be implemented as a junction field effect transistor (i.e., JFET), which only operates as a depletion device. The operation of the N-channel depletion mode MOSFET is similar to the operation of an N-channel JFET, and the operation of a P-channel depletion mode MOSFET is similar to the operation of a P-channel JFET.

For an N-channel depletion mode MOSFET, the threshold voltage is negative (i.e., −V_{T}). The N-channel depletion mode MOSFET is ON so that a nonzero drain-source (I_{DS}) current exists when the voltage between the gate and the source (i.e., V_{GS}) is positive. Only when V_{GS} is made negative (e.g., −V_{GS}<−V_{T}) does the N-channel depletion mode MOSFET turn OFF so that I_{DS} is pinched off.

For a P-channel depletion mode MOSFET, the threshold voltage is positive (i.e., +V_{T}). The P-channel depletion mode MOSFET is ON so that a nonzero drain-source (I_{DS}) current exists when the voltage between the gate and the source (i.e., V_{GS}) is negative. Only when V_{GS} is made positive (e.g., V_{GS}>V_{T}) does the P-channel depletion mode MOSFET turn OFF so that I_{DS} is pinched off.

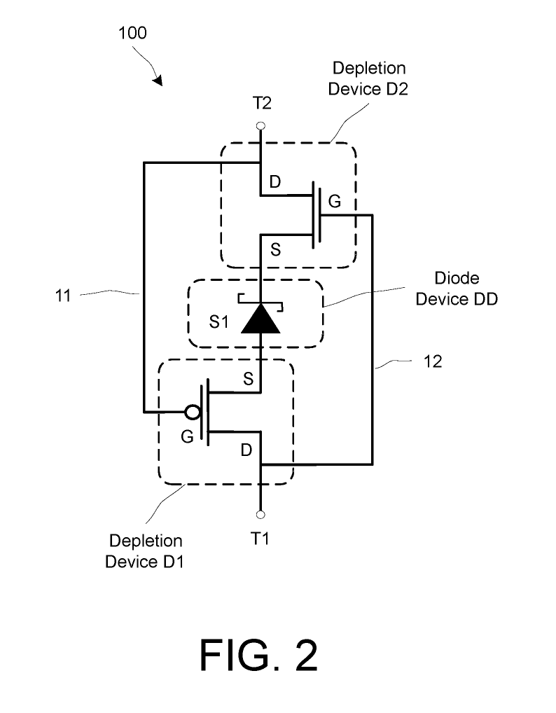

FIG. 2 is a diagram that illustrates an implementation of the diode circuit 100 shown in FIGS. 1A and 1B. As shown in FIG. 2, the diode device DD is a Schottky device S1 that has an anode (e.g., anode terminal) and a cathode (e.g., cathode terminal). The depletion device D1 is a P-channel depletion device (e.g., P-type metal oxide semiconductor field effect transistor (MOSFET) device, junction field effect transistor (JFET) device), and the depletion device D2 is an N-channel depletion mode device (e.g., N-type MOSFET device, JFET device). The N-channel depletion mode device is electrically coupled to the cathode of the Schottky device and the P-channel depletion mode device is electrically coupled to the anode of the Schottky device.

As shown in FIG. 2, the N-channel depletion mode device (i.e., D2) has a source S electrically coupled to the cathode of the Schottky device S1. The N-channel depletion mode device (i.e., D2) has a drain D at a terminal T2 (e.g., output terminal) of the diode circuit 100. The P-channel depletion mode device (i.e., D1) has a source S electrically coupled to the anode of the Schottky device. The P-channel depletion mode device (i.e., D1) has a drain D at a terminal T1 (e.g., an input terminal) of the diode circuit 100.

The N-channel depletion mode device has a gate G electrically coupled to the drain D of the P-channel depletion mode device via connection 12, or put another way, a gate of the N-channel depletion mode device is electrically coupled to the input terminal (T1) of the diode circuit 100. The P-channel depletion mode device has a gate G electrically coupled to the drain D of the N-channel depletion mode device via connection 11, or put another way, a gate of the P-channel depletion mode device is electrically coupled to the output terminal (T2) of the diode circuit 100.

The N-channel depletion mode device and the P-channel depletion mode device are both in an OFF-state when a negative voltage is applied between the terminal T1 and the terminal T2 of the diode circuit 100. In other words, the N-channel depletion mode device and the P-channel depletion mode device are both in an off-state when a voltage at the terminal T2 is higher than a voltage at the terminal T1 of the diode circuit 100. In such implementations, the diode circuit 100 is reverse-biased. Also, in such implementations, the Schottky device S1 is reverse-biased. When a negative voltage is applied between the terminal T1 and the terminal T2 of the diode circuit 100, both of the depletion mode devices are in an OFF-state because a gate-to-source voltage (V_{GS}) of the N-channel depletion mode device is negative and a V_{GS} of the P-channel depletion mode device is positive.

The N-channel depletion mode device and the P-channel depletion mode device block current of the diode circuit 100 when the diode circuit 100 is in the reverse-biased mode. In other words, the N-channel depletion mode device and the P-channel depletion mode device each can have a high impedance (e.g., resistance) when the diode circuit 100 is in the reverse-biased mode. The N-channel depletion mode device and the P-channel depletion mode device can each have a high impedance relative to the impedance (e.g., resistance) of the Schottky device S1 when the diode circuit 100 is in the reverse-biased mode. The diode circuit 100 may not leak (e.g., leak in an undesirable fashion even though the Schottky device S1 is leaky) because of the high impedance of the N-channel depletion mode device and the P-channel depletion mode devices. In such implementations, the diode circuit 100 can function essentially as an open circuit because there is very low leakage.

In some implementations, the P-channel depletion mode device and the N-channel depletion mode device can be configured so that the P-channel depletion mode device and the N-channel depletion mode device are both OFF when the negative voltage difference between terminal T1 and T2 is above a target voltage (e.g., threshold voltage for the diode circuit 100). In some implementations, the threshold voltage (e.g., absolute value of the threshold voltage) of the N-channel depletion mode device and/or the P-channel depletion mode device can be greater than 1 volt (e.g., 2 volts, 4 volts, 8 volts). In some implementations, the negative voltage difference between terminal T1 and T2 should be sufficiently high (e.g., relative to a threshold voltage), when in the reverse-biased mode, to turn-off both the P-channel depletion mode device and the N-channel depletion mode device.

The N-channel depletion mode device and the P-channel depletion mode device are both in an ON-state when a positive voltage is applied between the terminal T1 and the terminal T2 of the diode circuit 100. In other words, the N-channel depletion mode device and the P-channel depletion mode device are both in an ON-state when a voltage at the terminal T1 is higher than a voltage at the terminal T2 of the diode circuit 100. In such implementations, the diode circuit 100 is forward-biased. Also, in such implementations, the Schottky device S1 is forward-biased. The N-channel depletion mode device and the P-channel depletion mode device allow current to flow through the diode circuit 100 when a positive voltage is applied between the terminal T1 and the terminal T2.

The N-channel depletion mode device and the P-channel depletion mode can be configured to have very low voltage drop across their respective channels. Specifically, the N-channel depletion mode device and the P-channel depletion mode can be configured to have a relatively low voltage drop across their channels as compared with the Schottky device S1. Because the N-channel depletion mode device and the P-channel depletion mode are ON and low resistance when the diode circuit 100 is forward-biased, the diode circuit 100 functions as a Schottky diode. When the diode circuit 100 is forward-biased, the Schottky device S1 is also forward-biased and is the primary device of the diode circuit 100.

As noted above, because of the inclusion of the N-channel depletion mode device and the P-channel depletion mode, the Schottky device S1 can be made larger than otherwise would be possible because the N-channel and the P-channel depletion mode devices compensate for reverse-biased leakage issues of the Schottky device S1. In other words, adding the N-channel and the P-channel depletion mode devices allows for a larger Schottky diode to be used to reducing forward voltage while still reducing reverse leakage.

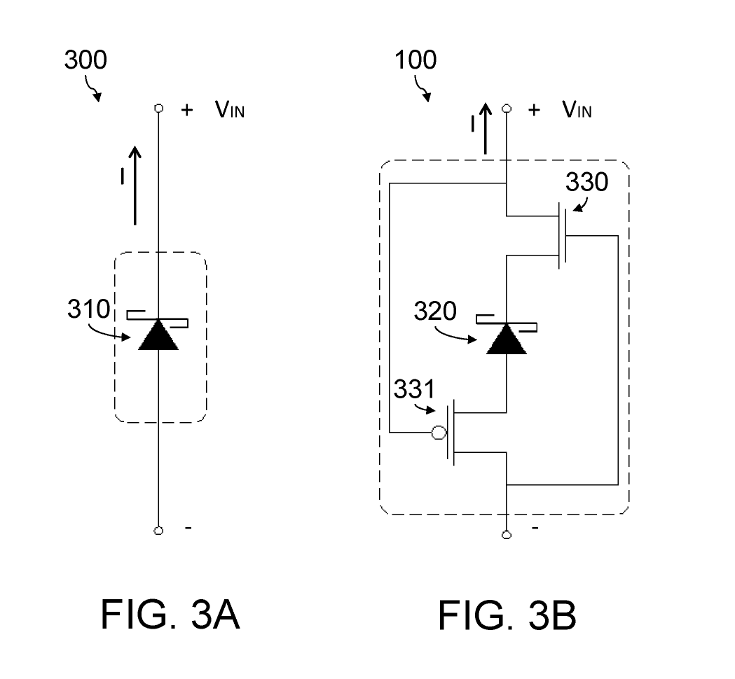

Two example diode circuits are simulated and compared to help understanding. FIGS. 3A and 3B schematically illustrate the two example diode circuits. A diode circuit 300 utilizing a single Schottky diode is shown in FIG. 3A, and the disclosed diode circuit 100 utilizing the combination of a Schottky diode and depletion devices is shown in FIG. 3B. The Schottky diode 310 in FIG. 3A is selected to provide a small leakage current, whereas the Schottky diode 320 in FIG. 3B is selected to small forward voltage drop (and large forward current). Accordingly, the Schottky diode 310 of the FIG. 3A diode circuit is smaller than the Schottky diode 320 of the FIG. 3B diode circuit. The diode circuit 100 of FIG. 3B utilizes a P-type, depletion-mode MOSFET 331 and an N-type, depletion-mode MOSFET 330. Each MOSFET has a threshold voltage V_{T} (e.g., ±8V) at which the devices turn ON/OFF.

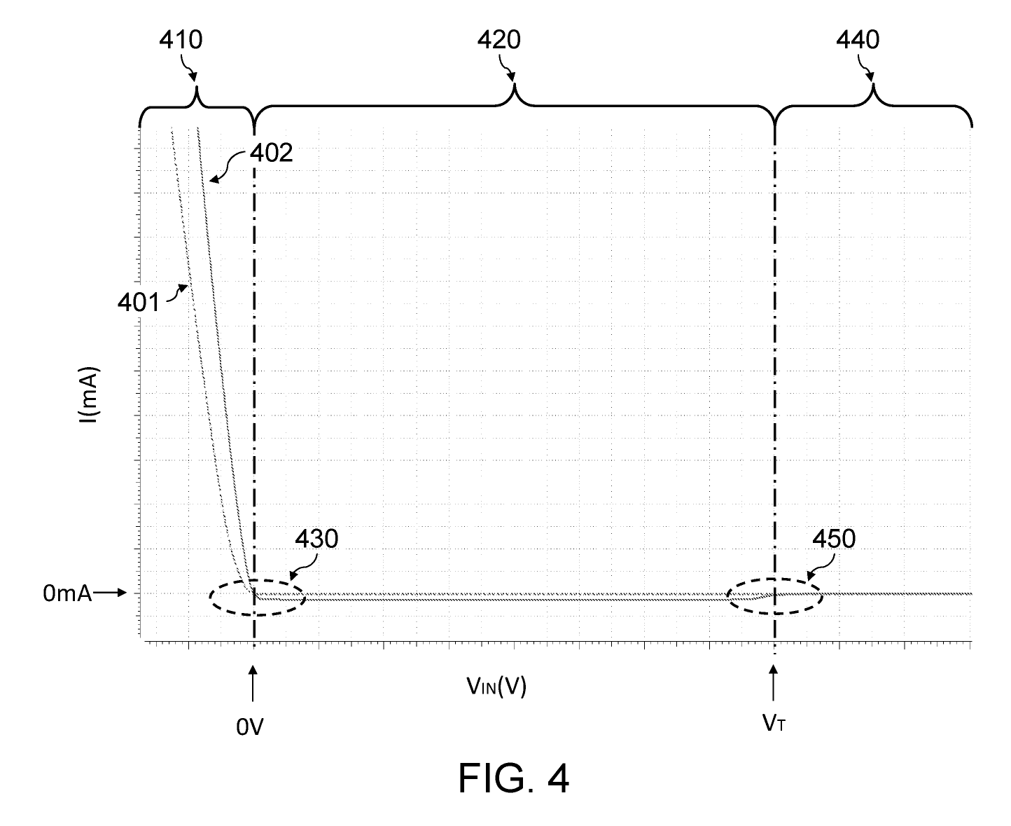

The two circuits are simulated to illustrate the current verses voltage for the polarities defined in FIGS. 3A and 3B. The simulation results are shown in FIG. 4. In FIG. 4, the diode circuit 300 of FIG. 3A is shown as the dotted line 401 whereas the diode circuit 100 of FIG. 3B is shown as the solid line 402. As shown, both diode circuits conduct current for a range of applied voltages (i.e., V_{IN}) corresponding to a forward-biased condition 410. The forward current of the diode circuit of FIG. 3B can be larger due to the size difference between the implementations. As mentioned, the Schottky diode 320 of FIG. 3B is larger than the Schottky diode 310 of FIG. 3A. The larger size corresponds to a lower resistance in the forward-bias condition 410 (i.e., ON state), which in turn, corresponds to a lower forward voltage drop across the diode circuit 100 of FIG. 3B. This operation of the disclosed diode circuit 100 in the ON state can be advantageous for applications that require efficient conduction of high currents.

The smaller Schottky diode 310 is expected to have a smaller leakage current than the larger Schottky diode 320. The simulation results shown in FIG. 4 illustrate this relationship for the range of applied voltages (V_{IN}) between zero volts (0V) and the threshold voltage (V_{T}) of the depletion mode devices (e.g., 8V). In this range, the Schottky diode is reversed biased (i.e., high resistance) but the P-type, depletion-mode MOSFET 331 and an N-type, depletion-mode MOSFET 330 are still conducting in an ON state because the voltage at each gate has not exceeded the threshold voltage of the devices. Accordingly, in this range of V_{IN}, the diode circuit 100 may be said to correspond to a partially-reversed-biased condition 420 and the leakage current is limited (i.e., set) by the Schottky diode 320. The leakage current of the smaller Schottky diode 310 of FIG. 3A (i.e., represented by the dotted line 401) is smaller than the larger Schottky diode 320 of FIG. 3B in the partially-reversed-biased condition 420.

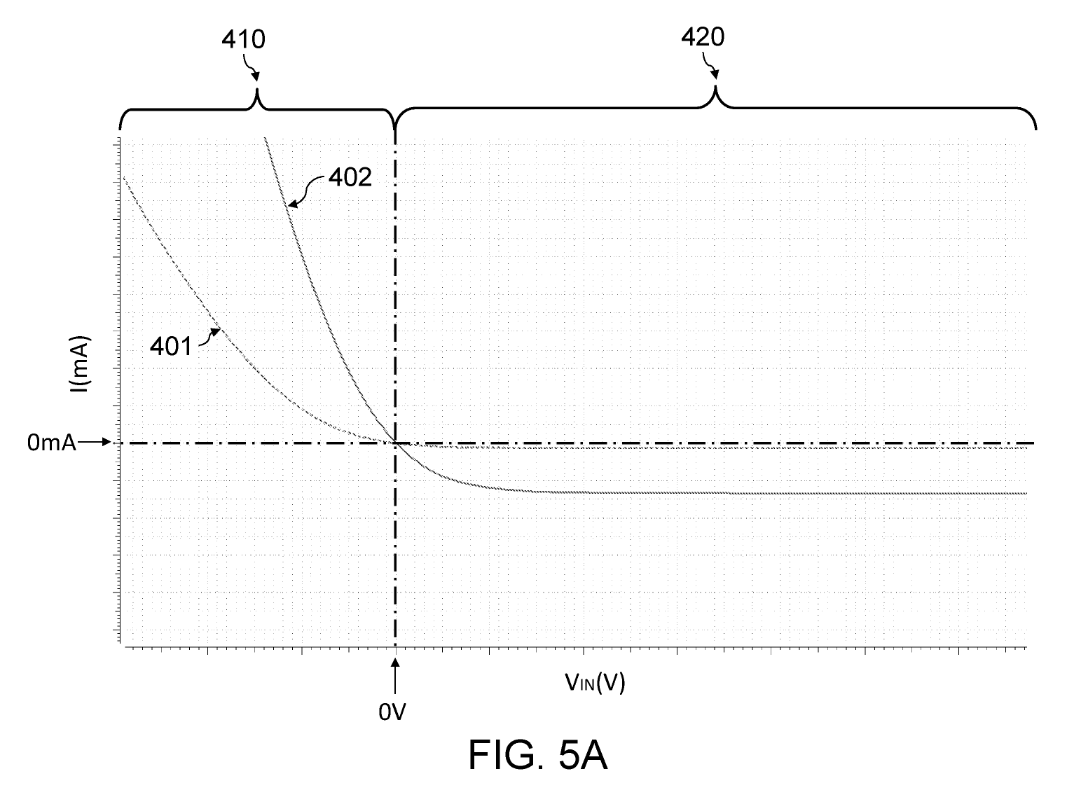

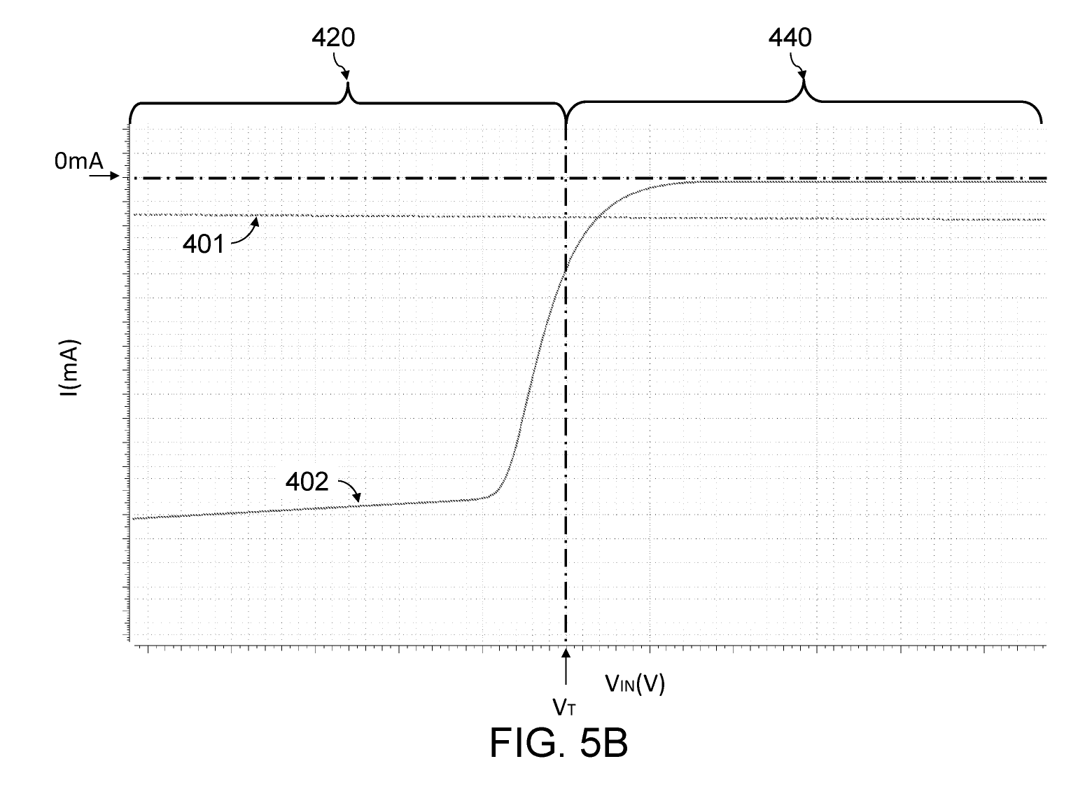

FIG. 5A illustrates a portion 430 of FIG. 4 for clarity. As shown the larger Schottky diode when operating alone provides more current for V_{IN} in a range 410 corresponding to forward-biased operation (i.e., negative voltages for the polarity shown in FIGS. 3A, 3B) but has much more leakage current for V_{IN} in a range 420 corresponding to partially reversed biased 420 operation. For example, the leakage current for the diode circuit 300 of FIG. 3A may be 10 mA while the leakage current for the diode circuit of FIG. 3B in the partially reversed-bias condition may be more than 10 times this amount (e.g., >100 mA).

Returning to FIG. 4, as the applied voltage V_{IN} is increased (i.e., as the reverse-bias increases), the P-type, depletion-mode MOSFET 331 and an N-type, depletion-mode MOSFET 330 change (i.e., switch, turn) from a highly conductive mode (i.e., ON) to a highly resistive mode (i.e., OFF), thereby increasing the resistance of the diode circuit 100 to the leakage current (i.e., −I). As shown in FIG. 4, for V_{IN} in a range of voltages at around V_{T} and higher, the two depletion mode devices are switched OFF to further reduce the leakage current. Accordingly, in this range 440 of V_{IN}, the diode circuit 100 may be said to be fully reversed-biased and the leakage current is limited (i.e., set) by the Schottky diode 320, the P-type, depletion-mode MOSFET 331 and/or the N-type, depletion-mode MOSFET 330.

FIG. 5B illustrates a portion 450 of FIG. 4 for clarity. The leakage current can be limited by the leakage of the depletion devices in an OFF state, which can be 1000 times lower than the leakage current of the Schottky diode 310 (i.e., the smaller Schottky diode). For example, the leakage current for the diode circuit 300 of FIG. 3A may be 10 mA while the leakage current for the diode circuit of FIG. 3B in the fully reversed bias condition may be 10 micro amps (μA) or less. In other words, the reverse leakage current through the Schottky diode may be reduced by at least a factor of 100 when the depletion mode devices are in the OFF state.

The diode circuit 100 of FIG. 3B facilitates the use of a larger Schottky diode to provide efficient and high current operation in a forward-bias condition, without sacrificing the resistance to a leakage current provided the reverse-bias voltage is above a threshold voltage. The depletion mode devices may have the same threshold or different thresholds. For implementations in which the threshold voltages are different for each depletion device, the fully reversed bias condition is satisfied when the reverse-bias voltage is above the higher of the two different threshold voltages so that both devices are in an OFF condition.

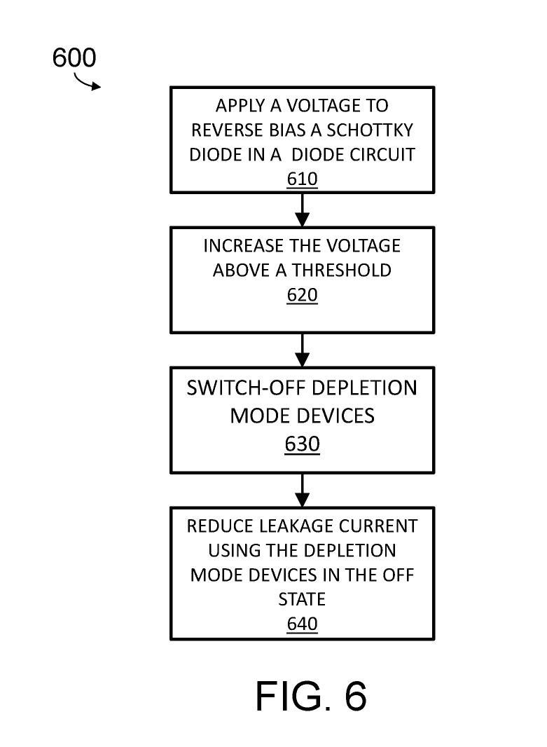

A method for reducing leakage is shown in FIG. 6. The method 600 begins with applying 610 a voltage (e.g., V_{IN}) to reverse-bias a Schottky diode in a diode circuit, such as shown in FIG. 3B. The applied voltage is then increased 620 to above a threshold (e.g., V_{T}) to switch-off 630 depletion mode devices in the diode circuit (i.e., place the depletion mode devices in an OFF condition). The leakage current through reversed biased Schottky diode is then reduced 640 using the resistance of the depletion mode devices in the OFF condition.

One system that can benefit from the circuits and method disclosed herein is a solar cell system (e.g., solar panel). For example, the disclosed diode circuits may be used as bypass diodes to allow for a string of series connected solar cells to safely (e.g., without damage) supply power even when one or more of the solar cells are shaded. The solar cells can also be referred to as photovoltaic cells.

Each solar cell in a string (also can be referred to an array, series, or set) generates a voltage and sources a current when it is exposed to (i.e., illuminated by, irradiated with) light (e.g., sunlight). If one (or more) of the solar cells is shaded (i.e., blocked or attenuated exposure), however, its voltage drops and instead of acting as a source of current it acts as a sink. When this happens damages to the solar panel may occur. To prevent damage, a solar panel can utilize bypass diodes connected in parallel with each solar cell. The bypass diodes typically operate in a reverse-biased condition and have little (or no) effect on the operation of the solar cell, the string of solar cells, or the solar panel. A bypass diode can be forward-biased to short circuit the solar cell in the string so that it is effectively removed from the string when the voltage of a solar cell drops (i.e., due to shading). It is desirable that the bypass diodes operate efficiently to prevent significant accumulation of loss in the solar cell system. The disclosed circuits and techniques provide a diode circuit that has efficient operation for a solar cell system.

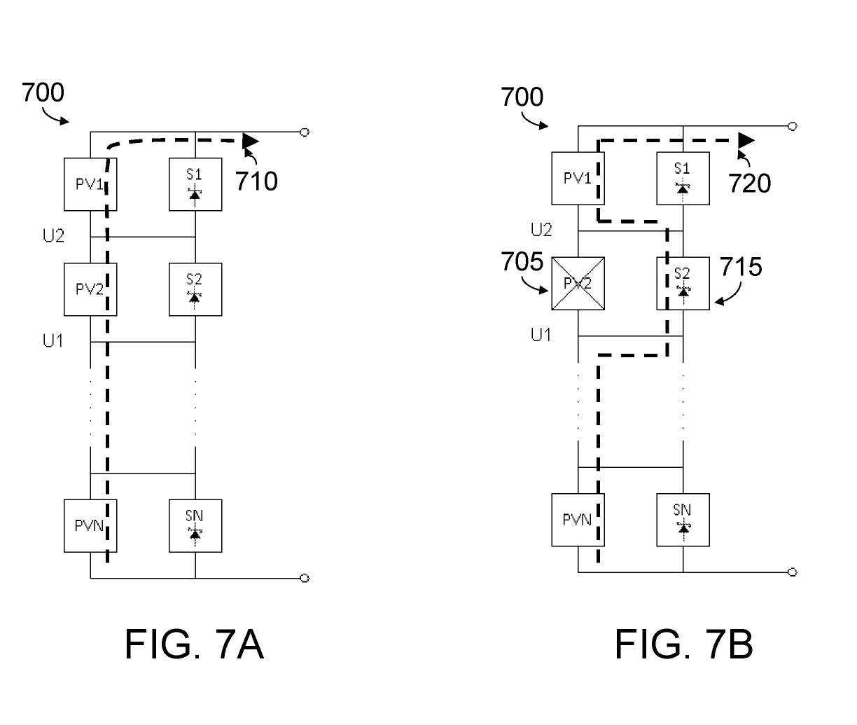

FIGS. 7A and 7B are diagrams that illustrate diode circuits S1 through SN included in a solar cell system 700. The diode circuits S1 through SN (which can collectively be referred to as diode circuits S) are included as part of a solar cell bypass circuit to bypass one or more of the solar cells PV1 through PVN (which can collectively be referred to as solar cells PV) within the solar cell system 700. Specifically, the diode circuits S are used in the solar cell system to bypass a particular solar cell if it is inactive (e.g., shaded). Bypassing an inactive solar cell PV can reduce wasted power and can improve the efficiency of the solar cell system 700.

In this implementation, each of the diode circuits S corresponds with (e.g., is connected in parallel with) a solar cell PV. Although the individual components of the diode circuits S is not shown, the orientation (forward-bias orientation, reverse-bias orientation) of each of the diode circuits S is illustrated by the Schottky diode symbol shown in each of the diode circuits S. In some implementations, each of the solar cells PV can include multiple cells. In some implementations, one or more of the solar cells PV (or collections thereof), when active or generating power, can be configured to produce a voltage between a few volts and tens of volts (e.g., between, for example, 12 V to 40 V).

As shown in FIG. 7A, all of the solar cells PV are active so none of the solar cells is bypassed. Current is flowing through the solar cells PV along a first path 710 because each of the solar cells PV is in a generator (e.g., generation) mode. The diode circuits S are reverse-biased because the voltage across the terminals of each of the individual diode circuits S is negative due to the voltage produced by a corresponding one of the solar cells PV. Thus, the bypass protection provided by each of the diode circuits S within the solar cell system 700 is in standby. For example, the solar cell PV2 produces a voltage with a voltage at U2 is higher than a voltage U1. Accordingly, the diode circuit S2 is reverse-biased and is not conducting current. The depletion mode devices, which are normally-on, within the diode circuit S2 are switched OFF.

As shown in FIG. 7B, one of the solar cells PV2 705 is inactive (e.g., changes to a resistive mode, changes to a resistive mode in response to being shaded) as shown by an X. Current is flowing through a subset of the solar cells PV and through a subset of the diode circuits S along a second path 720. Specifically, the solar cell PV2 is bypassed using the diode circuit S2 715. All of the diode circuits S are reverse-biased except for diode circuit S2 because the voltage across the terminals of the individual diode circuit S2 is positive due to the voltage (or lack thereof) across the corresponding solar cell PV2. Specifically, the solar cell PV2 705 does not produce a voltage difference, or a very low voltage difference, between U1 and U2. Accordingly, the diode circuit S2 715 is forward-biased (by default) and conducts current to bypass the solar cell PV2. The depletion mode devices, which are normally-on, within the diode circuit S2 will be ON. The diode circuit S2 is shunting around the solar cell PV2 when the diode circuit S2 in the forward-biased mode.

Each diode circuit may include depletion mode devices that are reversed biased when the voltage across the solar cell is above a threshold. For example, when a solar cell is active or generating power it can produce a voltage of around 12 to 40 volts (V). For a solar cell operating at 12 volts, the depletion mode devices have a threshold voltage V_{T} of about −8 volts. If the diode circuit is forward-biased, the depletion mode devices can have a V_{GS}−V_{T} value of about 8 voltages, which is enough to turn the depletion mode devices ON with a low resistance and low voltage drop. If the diode circuit is reverse-biased, the depletion mode devices can have a V_{GS}−V_{T} value of about −4V, which is enough to turn them OFF completely with a high resistance and low leakage current.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Implementations of the various techniques described herein may be implemented in (e.g., included in) digital electronic circuitry, or in computer hardware, firmware, software, or in combinations of them. Implementations of the various techniques described herein may be implemented in special purpose logic circuitry, e.g., an ASIC (application specific integrated circuit).

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components, and/or features of the different implementations described.

What is claimed is:

1. A diode circuit, comprising:
a diode device having an anode and a cathode;
an N-channel depletion mode device electrically coupled between the cathode of the diode device and an output terminal of the diode circuit; and
a P-channel depletion mode device electrically coupled between the anode of the diode device and an input terminal of the diode circuit.

2. The diode circuit according to claim 1, wherein the diode device is a Schottky diode.

3. The diode circuit according to claim 1, wherein the N-channel depletion mode device and the P-channel depletion mode device are in an ON state and conduct a forward current through the diode device when a forward-bias voltage is applied to the diode circuit, the forward-bias being a positive voltage between the input terminal and the output terminal of the diode circuit.

4. The diode circuit according to claim 1, wherein the N-channel depletion mode device and the P-channel depletion mode device are in an OFF state and resist a reverse leakage current through the diode device when a reverse-bias voltage is applied to the diode circuit, the reverse-bias voltage being a negative voltage between the input terminal and the output terminal of the diode circuit.

5. The diode circuit according to claim 4, wherein the reverse-bias voltage applied to the diode circuit is above a threshold voltage of the N-channel depletion mode device and a threshold voltage of the P-channel depletion mode device.

6. The diode circuit according to claim 5, wherein the threshold voltage of the N-channel depletion mode device and the threshold voltage of the P-channel depletion mode device are the same voltage.

7. The diode circuit according to claim 1, wherein the N-channel depletion mode device and the P-channel depletion mode device are in an ON state and conduct a reverse leakage current through the diode device when a reverse-bias voltage is applied to the diode circuit that is below a threshold voltage of the N-channel depletion mode device and a threshold voltage of the P-channel depletion mode device.

8. The diode circuit of claim 1, wherein the N-channel depletion mode device is a metal oxide semiconductor field effect transistor (MOSFET) device.

9. The diode circuit of claim 1, wherein the P-channel depletion mode device is a metal oxide semiconductor field effect transistor (MOSFET) device.

10. The diode circuit of claim 1, wherein the N-channel depletion mode device is a junction field effect transistor (JFET) device.

11. The diode circuit of claim 1, wherein the P-channel depletion mode device is a junction field effect transistor (JFET) device.

12. The diode circuit of claim 1, wherein a gate of the N-channel depletion mode device is electrically coupled to the input terminal of the diode circuit.

13. The diode circuit of claim 1, wherein a gate of the P-channel depletion mode device is electrically coupled to the output terminal of the diode circuit.

14. The diode circuit of claim 1, wherein the N-channel depletion mode device has a source electrically coupled to the cathode of the diode device, the P-channel depletion mode device has a source electrically coupled to the anode of the diode device.

15. The diode circuit of claim 14, wherein the N-channel depletion mode device has a drain at the output terminal of the circuit, and the P-channel depletion mode device has a drain at the input terminal of the circuit.

16. The diode circuit of claim 1, wherein the diode circuit is a bypass diode for a solar cell system.

17. A method for reducing a reverse leakage current in a diode circuit, the method comprising:
applying a reverse-bias voltage to terminals of the diode circuit, the reverse-bias voltage generating the reverse leakage current through a diode that is electrically coupled between a pair of depletion mode devices in the diode circuit;
increasing the reverse-bias voltage applied to the diode circuit to a voltage at or above a threshold voltage to configure the pair of depletion mode devices in the diode circuit in an OFF state; and
blocking the reverse leakage current using the depletion mode devices in the OFF state to reduce the reverse leakage current in the diode circuit.

18. The method for reducing reverse leakage current in a diode circuit according to claim 17, wherein the pair of depletion mode devices includes an N-channel depletion mode device and a P-channel depletion mode device.

19. A solar cell system comprising:
a plurality of solar cells electrically coupled in series; and
a diode circuit electrically coupled in parallel with each of the plurality of solar cells so that when the solar cell is illuminated the diode circuit is reverse biased and blocks current and when the solar cell is shaded the diode circuit is forward-biased and passes current to bypass the solar cell, the diode circuit including:
a Schottky diode having an anode and a cathode;
an N-channel depletion mode device electrically coupled between the cathode of the Schottky diode and an output terminal of the diode circuit; and
a P-channel depletion mode device electrically coupled between the anode of the Schottky diode and an input terminal of the diode circuit.

20. The solar cell system according to claim 19, wherein:
when the diode circuit is forward-biased, the N-channel depletion mode device, the P-channel depletion mode device, and the Schottky diode are in an ON state; and
when the diode circuit is reverse-biased, the N-channel depletion mode device, the P-channel depletion mode device, and the Schottky diode are in an OFF state.
